(19) United States
(12) Patent Application Publication
(10) Pub. No.: US 2008/0083983 A1
(43) Pub. Date: Apr. 10, 2008

(54) BUMP ELECTRODE INCLUDING PLATING LAYERS AND METHOD OF FABRICATING THE SAME

(75) Inventors: Hyang-sun JANG, Suwon-si (KR); Yong-hwan KWON, Suwon-si (KR); Un-byoung KANG, Hwseong-si (KR); Chung-sun Lee, Gunpo-si (KR); Woon-seong KWON, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/850,184

(22) Filed: Sep. 5, 2007

(30) Foreign Application Priority Data
Oct. 10, 2006 (KR) 10-2006-0098646

(51) Int. Cl. H01L 23/48; H01L 21/44

(52) U.S. Cl. 257/737; 257/E21.476; 257/E23.01; 438/613

(57) ABSTRACT

In one aspect, a bump electrode of a semiconductor device is formed by providing a substrate including a pad electrode, forming a seed layer over the pad electrode, and forming a mask layer over the seed layer which includes an opening aligned over the pad electrode. A barrier plating layer is electroplated within the opening over the seed layer, and a bump plating layer is electroplated over the barrier plating layer. The mask layer is removed, and the seed layer is etched using the bump plating layer as a mask.

### CROSS-REFERENCE TO RELATED PATENT APPLICATION

A claim of priority is made to Korean Patent Application No. 10-2006-0098646, filed Oct. 10, 2006, in the Korean Intellectual Property Office, the disclosure of which is incorporated herein in its entirety by reference.

### BACKGROUND OF THE INVENTION

1. Field of the Invention

The present invention generally relates to semiconductor devices, and more particularly, the present invention relates to bump electrodes and to methods of fabricating bump electrodes.

2. Description of the Related Art

Bump electrodes are typically utilized to connect semiconductor devices to external circuits. Particularly when compared with bonding wires, semiconductor devices having bump electrodes exhibit decreased signal noise, increased pad electrode density, and thin packaging profiles. Fabrication examples using bump electrodes include Tape Carrier Package (TCP) methods, Chip On Film (COF) methods, and Chip On Glass (COG) methods, which are generally used to mount drive units of flat-panel displays such as a Liquid Crystal Displays (LCD), a Plasma Display Panels (PDP) and an Organic Light Emitting Devices (OLED).

Bump electrodes are presently made of either solder or gold, each of which exhibits high conductivity and favorable ductility. However, the use of solder (which typically includes lead) suffers from environmentally related drawbacks. Further, while the use of gold is more environmentally friendly, it is relatively expensive using current bump electrode fabrication techniques.

### SUMMARY OF THE INVENTION

According to an aspect of the present invention, a method of forming a bump electrode of a semiconductor device is provided. The method includes providing a substrate including a pad electrode, forming a seed layer over the pad electrode, forming a mask layer over the seed layer which includes an opening aligned over the pad electrode, electroplating a barrier plating layer within the opening over the seed layer, electroplating a bump plating layer over the barrier plating layer, removing the mask layer, and etching the seed layer using the bump plating layer as a mask.

According to another aspect of the present invention, a method of forming a bump electrode of a semiconductor device is provided. The method includes providing a substrate including a pad electrode, forming a seed layer over the pad electrode, forming a mask layer over the seed layer which includes an opening aligned over the pad electrode, forming a barrier plating layer within the opening over the seed layer, forming a bump bonding layer over the barrier plating layer, forming a bump plating layer over the bump bonding layer, and removing the mask layer.

According to still another aspect of the present invention, a method of forming a bump electrode of a semiconductor device is provided. The method includes providing a substrate including a pad electrode, forming a seed layer over the pad electrode, forming a photoresist layer over the seed layer which includes an opening aligned over the pad electrode, electroplating a nickel plating layer within the opening, strike plating a gold strike layer over the nickel plating layer, electroplating a gold plating layer over the gold strike layer, removing the photoresist layer, and etching the seed layer using the gold plating layer as a mask.

According to another aspect of the present invention, a bump electrode of a semiconductor device is provided. The bump electrode includes a pad electrode formed over a substrate, a seed layer located over the pad electrode, a barrier electroplate layer located over the seed layer, and a bump electroplate layer located over the barrier electroplate layer.

### BRIEF DESCRIPTION OF THE DRAWINGS

The above and other aspects and features of the present invention will become readily apparent from the detailed description that follows, with reference to the accompanying drawings, in which:

FIGS. 1A through 1G are sectional views for use in describing a method of forming a bump electrode of a semiconductor device according to one or more embodiments of the present invention;

FIGS. 2A and 2B are photographic images illustrating plated layers formed on a general pad electrode and a ground pad electrode, respectively, using a non-electroplating technique;

FIGS. 3A through 3D are photographic images of upper surfaces of bump electrodes having different plating layer thicknesses according to embodiments of the present invention; and

FIG. 4 is a graph showing a correlation between a rate of inferior bump electrode defect formation relative to the thickness of a plating layer.

### DETAILED DESCRIPTION OF EMBODIMENTS

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are presented to provide a thorough and complete disclosure, and to fully convey concepts of the invention to those skilled in the art. In the drawings, the thicknesses of layers and regions are exaggerated for clarity. Also, like reference numerals in the drawings denote like elements.

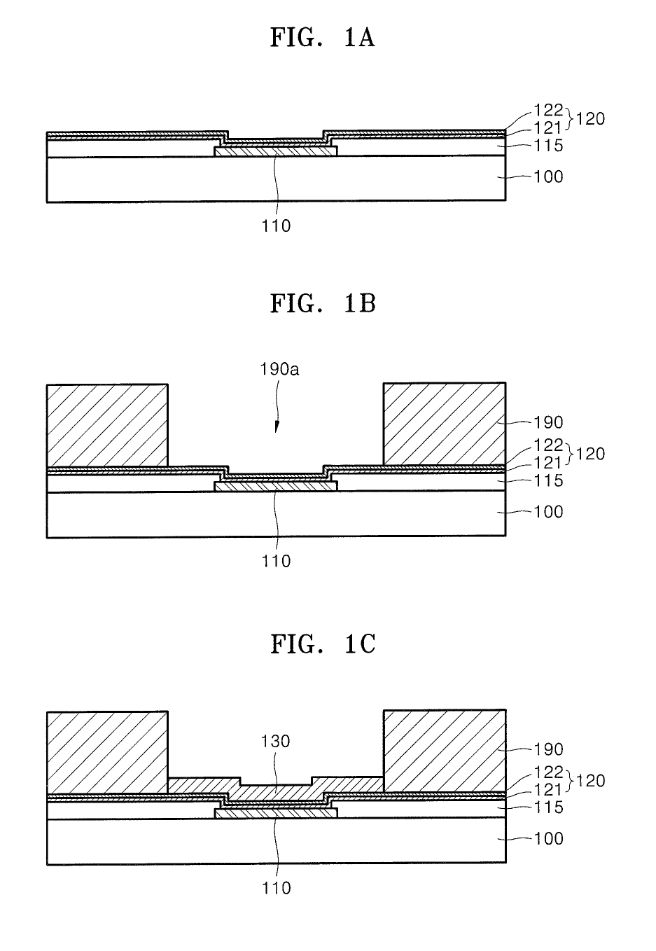

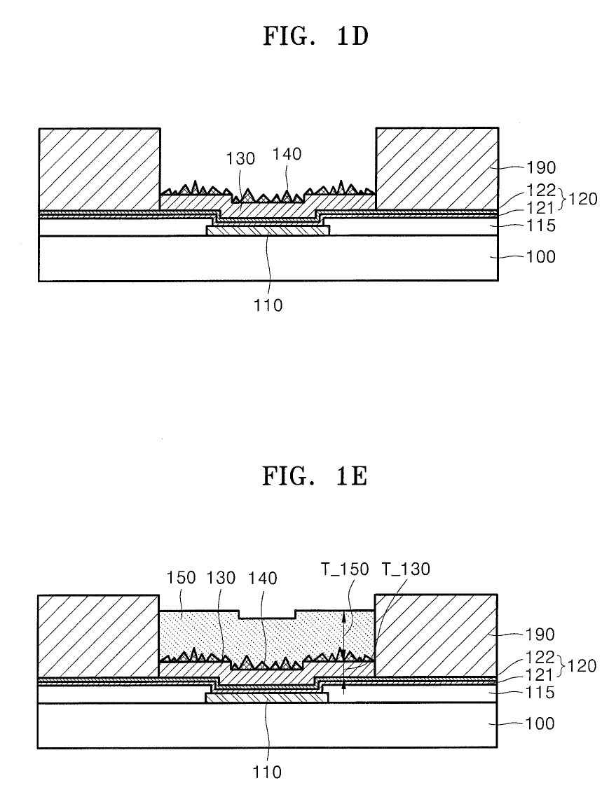

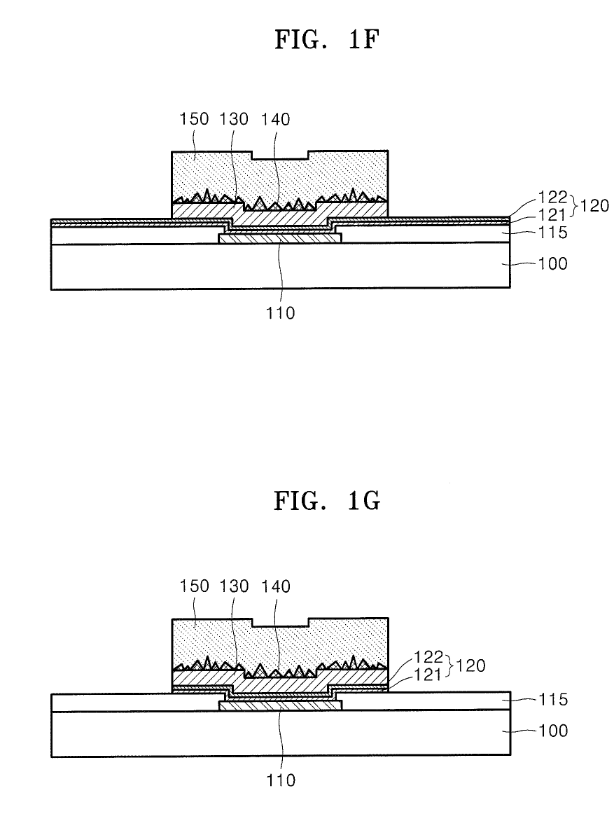

FIGS. 1A through 1G are sectional views for use in describing a method of forming a bump electrode of a semiconductor device according to one or more embodiments of the present invention.

Referring to FIG. 1A, a pad electrode 110 is formed on a semiconductor substrate 100 so as to be electrically connected to an electrical circuit (not shown) formed on and/or in the substrate 100. The pad electrode 110 may, for example, be an Al layer or a Cu layer.

A passivation layer 115 is formed over the substrate 100 and has an opening that exposes the pad electrode 110. The passivation layer 115 may, for example, be a silicon nitride film, a silicon oxide film, a silicon oxynitride film or a multi-layer film of two or more of these materials. Also, a polymer layer (not shown) may be formed on the passivation layer 115.

A seed layer 120 is then formed over the semiconductor substrate 100, the pad electrode 110 and the passivation layer 115. In this example, the seed layer 120 includes a seed bonding layer 121 and a wetting layer 122, which are sequentially stacked, and which preferably exhibit high etch selectivity relatively to a later formed bump plating layer. The seed bonding layer 121 improves adherence between the pad electrode 110 and the wetting layer 122, and may, for example, be composed of Ti, TiW, TiN, Cr, Al, or an alloy of two or more of these materials. The wetting layer 122 acts as a seed with respect to a barrier plating layer formed in a subsequent process, and may, for example, be composed of Cu, Ni, NiV, or an alloy of two or more of these materials. In one low-cost example exhibiting favorable characteristics, the seed bonding layer 121 is a Ti film, and the wetting layer 122 is a Cu. The seed bonding layer 121 and the wetting layer 122 may, for example, be successively formed by sputtering.

Referring to FIG. 1B, a mask layer 190 is formed on the seed layer 120. The mask layer 190 has an opening 190a aligned over the pad electrode 110 which partially exposes the seed layer 120. The mask layer 190 may, for example, be a photoresist layer.

Referring to FIG. 1C, a barrier plating layer 130 is formed by electroplating on the seed layer 120 exposed within the opening 190a. That is, for example, the semiconductor substrate 100 may be dipped in a plating tub (not shown) containing electroplating solution with a barrier metal. The semiconductor substrate 100 having the seed layer 120 defines a cathode of the electroplating process, and an anode (not shown) is separately defined within the electroplating tub. Current flows through the anode and the cathode to electrically attach the barrier metal onto the seed layer 120, thereby forming the barrier plating layer 130.

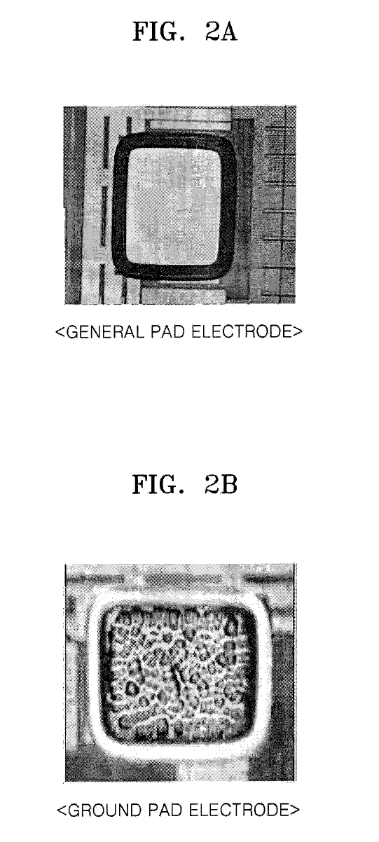

Electroplating of the barrier plating layer 130 allows for a uniform layer thickness on diverse types of pad electrodes. That is, in the case of non-electroplating, surface activating processing, i.e., Zincate processing is initially performed, thereby absorbing zinc ion groups onto a surface of the pad electrode. Here, in the case of a ground pad electrode electrically connected to the semiconductor substrate, electrons generated in association with ionization of a pad electrode material cannot be used to adsorb the zinc ion groups, but instead are leaked out to the semiconductor substrate. As shown in the photographic images of FIGS. 2A and 2B, since the zinc ion groups cannot be sufficiently absorbed onto the ground pad electrode, the formation of the plating layer differs greatly between a general pad electrode (FIG. 2A) and the ground pad electrode (FIG. 2B). Consequently, it is difficult to form a plating layer to a uniform thickness on different types of pad electrodes.

Accordingly, in the present embodiment, the barrier plating layer 130 is formed by electroplating that requires no surface activation processing such as Zincate processing on the seed layer 120 or the pad electrode 110. As a result, the barrier plating layer 130 having a uniform thickness can be formed on diverse kinds of pad electrodes 110 formed on the semiconductor substrate 100.

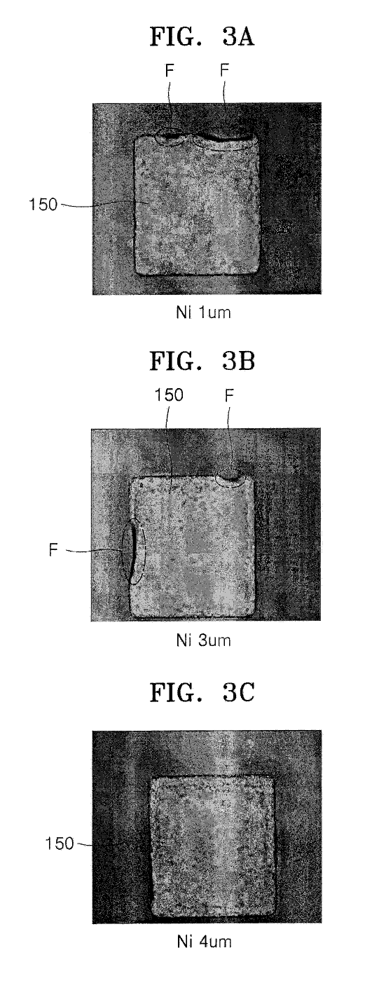

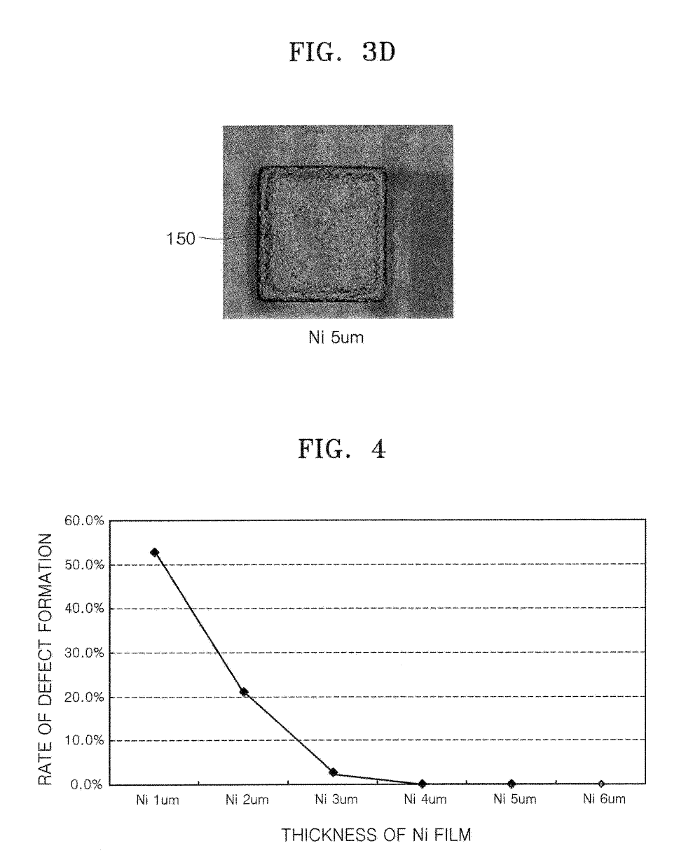

As will be explained later in connection with FIGS. 3A through 4, the barrier plating layer 130 preferably has a thickness of 4 μm or more, and more preferably, the barrier plating layer 130 has a thickness of 5 μm or more. Further, in consideration of preferred design constraints relative to bump electrode height, the barrier plating layer 130 preferably has a thickness of 15 μm or less. The barrier plating layer 130 may be a Ni film, a Pd film, an Ag film or an alloy of two or more of these films. Preferably, the barrier plating layer 130 is a Ni film so as to reduce processing costs and provide favorable adhesion and anti-corrosion properties.

Referring to FIG. 1D, in the example of this embodiment, a bump bonding layer 140 is formed on the barrier plating layer 130. The bump bonding layer 140 may be a strike plating layer formed by electrolytic strike plating to improve a bonding force. Strike plating is performed at a higher current density for a shorter time period than common plating.

Referring to FIG. 1E, a bump plating layer 150 is formed by electroplating on the bump bonding layer 140. Accordingly, similar to the barrier plating layer 130, the bump plating layer 150 can be formed with uniform thickness on diverse kinds of the pad electrodes 110 located on the semiconductor substrate 100. The bump plating layer 150 may, for example, be an Au film.

The bump plating layer 150 can be reliably bonded onto the barrier plating layer 130. That is, the bump bonding layer 140 prevents or minimizes lifting that might otherwise occur at an interfacial surface of the bump plating layer 150 and the barrier plating layer 130 due to a stress difference there between. The bump bonding layer 140 may be composed of a material which is identical to that of the bump plating layer 150.

Preferably, the barrier plating layer 130 is sufficiently thick (e.g., 4 μm or more) to prevent a solution of the bump plating layer 150 from permeating to the lower portion of the mask pattern 190 and contacting the seed layer 120. This is at least partly because the seed layer 120 can dissolve in the bump plating solution, which in turn can impede normal growth and formation of the bump plating layer 150. This can be especially problematic in the case where the wetting layer 122 of the seed layer 120 is a copper film, and the bump plating layer 150 is a gold film.

Referring to FIG. 1E, a thickness T_150 of the bump plating layer 150 is preferably greater than a thickness T_130 of the barrier plating layer 130. This may allow the bump plating layer 150 to be sufficiently pressed and spread when the finally-formed bump electrode is connected onto a circuit board, so that the semiconductor device and the circuit board can be reliably connected. Further, the bump bonding layer 140 prevents or minimizes lifting of the bump plating layer 150 from the barrier plating layer 130.

Referring to FIG. 1F, the mask pattern 190 is removed to expose the seed layer 120.

Referring to FIG. 1G, the bump plating layer 150 is used as a mask to etch the exposed seed layer 120. Thus, a bump electrode is obtained which includes the sequentially stacked seed layer 120, barrier plating layer 130, bump bonding layer 140, and bump plating layer 150.

The seed layer 120 preferably exhibits high etch selectivity to the bump plating layer 150 and the barrier plating layer 130, to thereby avoid etching of the bump plating layer 150 and the barrier plating layer 130 during etching the seed layer 120. This can minimize variations in the size and surface roughness of the bump plating layer 150 and the barrier plating layer 130.

Hereinafter, preferred examples will be presented for a better understanding of the present invention. However, the present invention is not limited to the following examples.

### EXAMPLE 1

An aluminum pad electrode is formed on a substrate, and a passivation layer exposing the pad electrode is formed on the pad electrode. Then, a Ti film and a Cu film are sequentially stacked on the pad electrode and the passivatfon layer using sputtering. A photoresist layer is formed on the Cu film, which is then exposed and developed, thereby forming an opening overlapping the pad electrode and exposing the Cu film in the photoresist layer. A nickel plating layer is formed on the Cu film exposed within the opening to have a thickness of about 1 μm using electroplating. A gold strike plating layer is formed on the nickel plating layer using electrolytic strike plating. A gold plating layer is formed on the gold strike plating layer using electroplating to have a thickness of 17 μm.

### EXAMPLE 2

The bump electrode is formed by the same method of Example 1 except that the nickel plating layer is formed to a thickness of 2 μm.

### EXAMPLE 3

The bump electrode is formed by the same method of Example 1 except that the nickel plating layer is formed to a thickness of 3 μm.

### EXAMPLE 4

The bump electrode is formed by the same method of Example 1 except that the nickel plating layer is formed to a thickness of 4 μm.

### EXAMPLE 5

The bump electrode is formed by the same method of Example 1 except that the nickel plating layer is formed to a thickness of 5 μm.

### EXAMPLE 6

The bump electrode is formed by same method of Example 1 except that the nickel plating layer to a thickness of 6 μm.

Images of upper surfaces of the bump electrodes formed according to Examples 1, 3, 4, and 5 are illustrated in FIGS. 3A through 3D, respectively. In these images (FIGS. 3A and 3B in particular), defects are denoted by reference character “F”.

Rates of defect formation of the bump electrodes of Examples 1 through 6 are shown in Table 1 below and in the graph of FIG. 4. The defect formation rates were obtained by examining the configuration of the bump electrodes in a plurality of chips, and calculating the number of the chips containing abnormal bump electrodes (defects) relative to the total number of chips.

TABLE 1

| | | Rate of defect |
|---|---|---|
| | Condition | formation |
| Example 1 | Ni 1 μm | 52.8% |
| Example 2 | Ni 2 μm | 21.2% |
| Example 3 | Ni 3 μm | 2.5% |
| Example 4 | Ni 4 μm | 0.2% |
| Example 5 | Ni 5 μm | 0.0% |
| Example 6 | Ni 6 μm | 0.0% |

Referring to Table 1 and FIG. 4, when the thickness of the nickel plating layer is less that 4 μm, the incidence of formation of defects F at an edge portion of the gold plating layer 150 (also see FIGS. 3A and 3B) increases. As discussed previously, if the nickel plating layer is too thin, the gold plating solution can permeate to contact and dissolve the underlying copper film, thus impeding normal growth of the gold plating layer.

In contrast, if the thickness of the nickel plating layer is 4 μm or greater, the edge portion of the gold plating layer exhibits minimal defects. Moreover, when the thickness of the nickel plating layer is 5 μm or greater, the edge portion of the gold plating layer exhibited no defect formation.

According to one or more embodiments as described above, the bump electrode may be only partially composed of gold, thus reducing costs. Also, the barrier plating layer and a bump plating layer may be formed by electroplating to allow for a uniform thickness of these layers on diverse types of pad electrodes. Further, the barrier plating layer may be formed of sufficient thickness (e.g., 4 μm or greater) to prevent or reduce defect formation of the bump plating layer, thereby improving a plating profile of the bump plating layer. Still further, a thickness of the bump plating layer may be greater than that of the barrier plating layer, thereby improving the reliability of a connection between the semiconductor device and a circuit board. Further, a bump bonding layer may be formed between the barrier plating layer and the bump plating layer, to improve the bonding reliability between the bump plating layer and barrier plating layer, particularly in the case where the bump plating layer is thicker than the barrier plating layer.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of forming a bump electrode of a semiconductor device, comprising:
providing a substrate including a pad electrode;
forming a seed layer over the pad electrode;
forming a mask layer over the seed layer which includes an opening aligned over the pad electrode;
electroplating a barrier plating layer within the opening over the seed layer;
electroplating a bump plating layer over the barrier plating layer;
removing the mask layer; and
etching the seed layer using the bump plating layer as a mask.

2. The method of claim 1, further comprising forming a bump bonding layer on the barrier plating layer before electroplating the bump plating layer.

3. The method of claim 2, wherein the bump bonding layer and the bump plating layer are composed of a same material.

4. The method of claim 2, wherein the bump bonding layer is formed by strike plating.

5. The method of claim 1, wherein the bump plating layer is thicker than the barrier plating layer.

6. The method of claim 5, further comprising forming a bump bonding layer on the barrier plating layer before electroplating the bump plating layer.

7. The method of claim 1, wherein a thickness of the barrier plating layer is at least 4 μm.

8. The method of claim 7, wherein the thickness of the barrier plating layer is at most 15 μm.

9. The method of claim 1, wherein the barrier plating layer comprises a material selected from the group consisting of Ni, Pd, Ag and an alloy of two or more of these materials.

10. The method of claim 1, wherein the bump plating layer comprises Au.

11. The method of claim 1, wherein the seed layer comprises a seed bonding layer and a wetting layer sequentially stacked over the pad electrode.

12. The method of claim 11, wherein the seed bonding layer comprises a material selected from the group consisting of Ti, TiN, TiW, Cr, Al, and an alloy of two or more of these materials.

13. The method of claim 11, wherein the wetting layer comprises a material selected from the group consisting of Cu, Ni, NiV, and an alloy of two or more of these materials.

14. A method of forming a bump electrode of a semiconductor device, comprising:
providing a substrate including a pad electrode;
forming a seed layer over the pad electrode;
forming a mask layer over the seed layer which includes an opening aligned over the pad electrode;
forming a barrier plating layer within the opening over the seed layer;
forming a bump bonding layer over the barrier plating layer;
forming a bump plating layer over the bump bonding layer; and
removing the mask layer.

15. The method of claim 14, wherein the bump bonding layer and the bump plating layer are composed of a same material.

16. The method of claim 14, wherein the bump bonding layer is formed by strike plating.

17. The method of claim 14, wherein the bump plating layer is thicker than the barrier plating layer.

18. The method of claim 14, wherein a thickness of the barrier plating layer is at least 4 μm.

19. The method of claim 18, wherein the thickness of the barrier plating layer is at most 15 μm.

20. The method of claim 14, further comprising, after removing the mask layer, etching the seed layer using the bump plating layer as a mask.

21. The method of claim 14, wherein the seed layer comprises a seed bonding layer and a wetting layer sequentially stacked over the pad electrode.

22. A method of forming a bump electrode of a semiconductor device, comprising:
providing a substrate including a pad electrode;
forming a seed layer over the pad electrode;
forming a photoresist layer over the seed layer which includes an opening aligned over the pad electrode;
electroplating a nickel plating layer within the opening;
strike plating a gold strike layer over the nickel plating layer;
electroplating a gold plating layer over the gold strike layer;
removing the photoresist layer; and
etching the seed layer using the gold plating layer as a mask.

23. The method of claim 22, wherein the seed layer comprises a Ti layer and a Cu layer sequentially stacked over the pad electrode.

24. The method of claim 22, wherein a thickness of the nickel plating layer is at least 4 μm.

25. The method of claim 24, wherein the thickness of the barrier plating layer is at most 15 μm.

26. A bump electrode of a semiconductor device, comprising:
a pad electrode formed over a substrate;
a seed layer located over the pad electrode;
a barrier electroplate layer located over the seed layer; and
a bump electroplate layer located over the barrier electroplate layer.

27. The bump electrode of claim 26, wherein a thickness of the barrier electroplate layer is at least 4 μm.

28. The bump electrode of claim 27, wherein the thickness of the barrier electroplate layer is at most 15 μm.

29. The bump electrode of claim 26, further comprising a bump bonding layer located between the bump electroplate layer and the barrier electroplate layer.

30. The bump electrode of claim 29, wherein the bump bonding layer and the bump electroplate layer are comprised of a same material.

31. The bump electrode of claim 26, wherein the bump electroplate layer is thicker than the barrier electroplate layer.

32. The bump electrode of claim 31, further comprising a bump bonding layer located between the bump electroplate layer and the barrier electroplate layer.
